(19) United States
(12) Patent Application Publication
(10) Pub. No.: US 2026/0120998 A1
(43) Pub. Date: Apr. 30, 2026

(54) PLASMA PROCESSING APPARATUS AND PLASMA PROCESSING METHOD

(71) Applicant: Tokyo Electron Limited, Tokyo (JP)

(72) Inventors: Yuto KOSAKA, Miyagi (JP); Takaharu SAINO, Miyagi (JP)

(73) Assignee: Tokyo Electron Limited, Tokyo (JP)

(21) Appl. No.: 19/003,190

(22) Filed: Dec. 27, 2024

Related U.S. Application Data
(63) Continuation of application No. PCT/JP2023/015225, filed on Apr. 14, 2023.

(30) Foreign Application Priority Data
Jun. 30, 2022 (JP) 2022-105668

(51) Int. Cl. H01J 37/32

(52) U.S. Cl. CPC H01J 37/32146

(57) ABSTRACT

A plasma processing apparatus includes a chamber, a substrate support, a radio-frequency power supply for generating source radio-frequency power, a bias power supply for generating electric bias, and a controller. The controller executes a first operation of supplying the source radio-frequency power, and a second operation of supplying the electric bias to the substrate support during the supply of the source radio-frequency power. A delay time length from a time at which the supply of the source radio-frequency power begins in the first operation until a time at which the supply of the electric bias begins in the second operation is set to be equal to or greater than a time length for an electron to reach an end of the substrate support or an end of a substrate on the substrate support from a center of the substrate support or a center of the substrate on the substrate support.

### CROSS-REFERENCE TO RELATED APPLICATIONS

This application is a bypass continuation application of international application No. PCT/JP2023/015225 having an international filing date of Apr. 14, 2023 and designating the United States, the international application being based upon and claiming the benefit of priority from Japanese Patent Application No. 2022-105668, filed on Jun. 30, 2022, the entire contents of each are incorporated herein by reference.

### TECHNICAL FIELD

Exemplary embodiments of the present disclosure relate to a plasma processing apparatus and a plasma processing method.

### BACKGROUND

A plasma processing apparatus is used in plasma processing of a substrate. The plasma processing apparatus uses bias radio-frequency power to draw ions from plasma generated inside a chamber into the substrate. Patent Document 1 discloses a plasma processing apparatus which modulates a power level and frequency of bias radio-frequency power.

### PRIOR ART DOCUMENT

### Patent Document

Patent Document 1: Japanese Laid-Open Patent Publication No. 2009-246091

### SUMMARY

According to one embodiment of the present disclosure, a plasma processing apparatus includes a chamber, a substrate support provided inside the chamber, a radio-frequency power supply configured to generate source radio-frequency power, a bias power supply electrically coupled to the substrate support and configured to generate electric bias for drawing ions to the substrate support, and a controller configured to control the radio-frequency power supply and the bias power supply. The controller is configured to execute a first operation of supplying the source radio-frequency power to generate plasma inside the chamber, and a second operation of supplying the electric bias to the substrate support during the supply of the source radio-frequency power. A delay time length from a time point at which the supply of the source radio-frequency power begins in the first operation until a time point at which the supply of the electric bias begins in the second operation is set to be equal to or greater than a reference time length. The reference time length is a time length for an electron to reach an end portion of the substrate support or an end portion of a substrate on the substrate support from a center of the substrate support or a center of the substrate on the substrate support.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating a configuration example of a plasma processing system.

FIG. 2 is a diagram illustrating a configuration example of a capacitively coupled plasma processing apparatus.

FIGS. 3A and 3B are timing charts, respectively, relating to the plasma processing apparatus according to one exemplary embodiment.

FIGS. 4A and 4B are timing charts, respectively, relating to the plasma processing apparatus according to one exemplary embodiment.

FIG. 5 is a flowchart of a plasma processing method according to one exemplary embodiment.

### DETAILED DESCRIPTION

Hereinafter, various exemplary embodiments will be described in detail with reference to the drawings. In addition, the same reference numerals will be given to the same or corresponding parts in each drawing. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

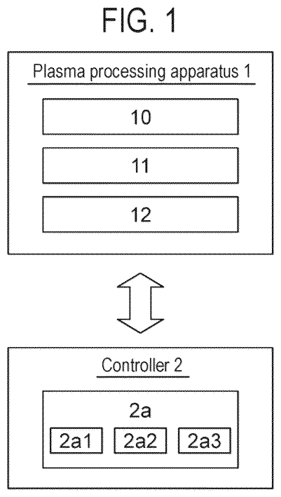

FIG. 1 is a diagram for explaining a configuration example of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 includes at least one gas supply port for supplying at least one processing gas to the plasma processing space therethrough, and at least one gas exhaust port for exhausting a gas from the plasma processing space therethrough. The gas supply port is connected to a gas supplier 20 described later. The gas exhaust port is connected to an exhaust system 40 described later. The substrate support 11 is arranged inside the plasma processing space, and has a substrate support surface for supporting a substrate thereon.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), or surface wave plasma (SWP).

The controller 2 processes computer-executable instructions that cause the plasma processing apparatus 1 to execute various processes described in the present disclosure. The controller 2 may be configured to control individual elements of the plasma processing apparatus 1 to execute various processes described herein. In one embodiment, a part or the entirety of the controller 2 may be included in the plasma processing apparatus 1. The controller 2 may include a processor 2al, a memory 2a2, and a communication interface 2a3. The controller 2 is implemented by, for example, a computer 2a. The processor 2al may be configured to perform various control operations by reading a program from the memory 2a2 and executing the read program. This program may be stored in the memory 2a2 in advance, or may be acquired via a medium when necessary. The acquired program is stored in the memory 2a2 and is read from the memory 2a2 by the processor 2a1 and executed. The medium may be various storage media readable by the computer 2a, or may be a communication line connected to the communication interface 2a3. The processor 2a1 may be a CPU (Central Processing Unit). The memory 2a2 may include a RAM (Random Access Memory), a ROM (Read Only Memory), an HDD (Hard Disk Drive), an SSD (Solid State Drive), or a combination thereof. The communication interface 2a3 may communicate with the plasma processing apparatus 1 via a communication line such as a LAN (Local Area Network) or the like.

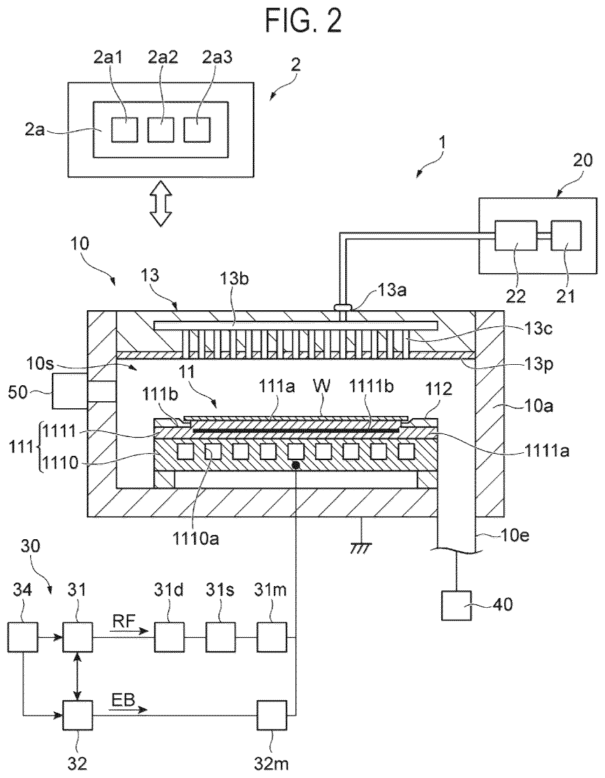

A configuration example of a capacitively coupled plasma processing apparatus will be described below as an example of the plasma processing apparatus 1. FIG. 2 is a diagram for explaining the configuration example of the capacitively coupled plasma processing apparatus.

The capacitively coupled plasma processing apparatus 1 includes a plasma processing chamber 10, a gas supplier 20, a power supply system 30, and an exhaust system 40. The plasma processing apparatus 1 further includes a substrate support 11 and a gas introducer. The gas introducer is configured to introduce at least one processing gas into the plasma processing chamber 10. The gas introducer includes a shower head 13. The substrate support 11 is arranged inside the plasma processing chamber 10. The shower head 13 is arranged above the substrate support 11. In one embodiment, the shower head 13 constitutes at least a part of the ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The substrate support 11 is electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is arranged on the central region 111a of the main body 111, and the ring assembly 112 is arranged on the annular region 111b of the main body 111 so as to surround the substrate W on the central region 111a of the main body 111. Therefore, the central region 111a is also called a substrate support surface for supporting the substrate W thereon, and the annular region 111b is also called a ring support surface for supporting the ring assembly 112 thereon.

In one embodiment, the main body 111 includes a base 1110 and an electrostatic chuck 1111. The base 1110 includes a conductive member. The electrostatic chuck 1111 is arranged on the base 1110. The electrostatic chuck 1111 includes a ceramic member 1111a and an electrostatic electrode 1111b arranged inside the ceramic member 1111a. The ceramic member 1111a has a central region 111a. In one embodiment, the ceramic member 1111a also has an annular region 111b. Another member surrounding the electrostatic chuck 1111, such as an annular electrostatic chuck or an annular insulating member, may have the annular region 111b. In this case, the ring assembly 112 may be arranged on the annular electrostatic chuck or the annular insulating member, or may be arranged on both the electrostatic chuck 1111 and the annular insulating member.

The ring assembly 112 includes one or more annular members. In one embodiment, the one or more annular members include one or more edge rings and at least one cover ring. The edge rings are made of a conductive or insulating material, and the cover ring is made of an insulating material.

Further, the substrate support 11 may include a temperature adjustment module configured to adjust a temperature of at least one of the electrostatic chuck 1111, the ring assembly 112, or the substrate to a target temperature. The temperature adjustment module may include a heater, a heat transfer medium, a flow path 1110a, or a combination thereof. A heat transfer fluid such as a brine or a gas flows through the flow path 1110a. In one embodiment, the flow path 1110a is formed in the base 1110, and one or more heaters are arranged inside the ceramic member 1111a of the electrostatic chuck 1111. Further, the substrate support 11 may include a heat-transfer gas supplier configured to supply a heat-transfer gas to a gap between a back surface of the substrate W and the central region 111a.

The shower head 13 is configured to introduce at least one processing gas from the gas supplier 20 into the plasma processing space 10s. The shower head 13 includes at least one gas supply port 13a, at least one gas diffusion chamber 13b, and a plurality of gas introduction holes 13c. The processing gas supplied to the gas supply port 13a passes through the gas diffusion chamber 13b and is introduced into the plasma processing space 10s via the gas introduction holes 13c. Further, the shower head 13 includes at least one upper electrode. In addition to the shower head 13, the gas introducer may include one or more side gas injectors (SGI) attached to one or more openings formed in the sidewall 10a.

The gas supplier 20 may include at least one gas source 21 and at least one flow rate controller 22. In one embodiment, the gas supplier 20 is configured to supply at least one processing gas from the corresponding gas source 21 via the corresponding flow rate controller 22 to the shower head 13. The flow rate controller 22 may include, for example, a mass flow controller or a pressure-controlled flow rate controller. Further, the gas supplier 20 may include at least one flow modulation device for modulating or pulsing a flow rate of the at least one processing gas.

The exhaust system 40 may be connected to, for example, the gas exhaust port 10e provided at the bottom of the plasma processing chamber 10. The exhaust system 40 may include a pressure regulation valve and a vacuum pump. An internal pressure of the plasma processing space 10s is adjusted by the pressure regulation valve. The vacuum pump may include a turbo-molecular pump, a dry pump, or a combination thereof.

The power supply system 30 includes a radio-frequency power supply 31 and a bias power supply 32. The radio-frequency power supply 31 constitutes the plasma generator 12 of one embodiment. The radio-frequency power supply 31 is configured to generate a source radio-frequency power RF. The source radio-frequency power RF has a source frequency f_{RF}. In other words, the source radio-frequency power RF has a sinusoidal waveform with the source frequency f_{RF}. The source frequency f_{RF} may fall within a range of 13 MHz to 100 MHz. The radio-frequency power supply 31 is electrically connected to a radio-frequency electrode via a matcher 31m and is configured to supply the source radio-frequency power RF to the radio-frequency electrode. The radio-frequency electrode may be provided inside the substrate support 11. The radio-frequency electrode may be the conductive member of the base 1110 or at least one electrode provided inside the ceramic member 1111a. Alternatively, the radio-frequency electrode may be an upper electrode. In addition, the upper electrode may include a ceiling plate 13p. When the source radio-frequency power RF is supplied to the radio-frequency electrode, plasma is generated from the gas inside the chamber 10.

The matcher 31m has a variable impedance. The variable impedance of the matcher 31m is set to reduce reflections from a load of the source radio-frequency power RF. The matcher 31m may be controlled by, for example, the controller 2.

The bias power supply 32 is electrically coupled to the substrate support 11. The bias power supply 32 is electrically connected to a bias electrode in the substrate support 11 and configured to supply electric bias EB to the bias electrode. The bias electrode may be the conductive member of the base 1110 or at least one electrode provided in the ceramic member 1111a. The bias electrode may be common to the radio-frequency electrode. When the electric bias EB is supplied to the bias electrode, ions from the plasma are attracted to the substrate W.

The electric bias EB has a waveform cycle CY and is periodically supplied from the bias power supply 32 to the bias electrode. The waveform cycle CY of the electric bias EB is defined by a bias frequency. The bias frequency is, for example, 100 kHz or higher and 50 MHz or lower. A time length of the waveform cycle CY of the electric bias EB is the reciprocal of the bias frequency.

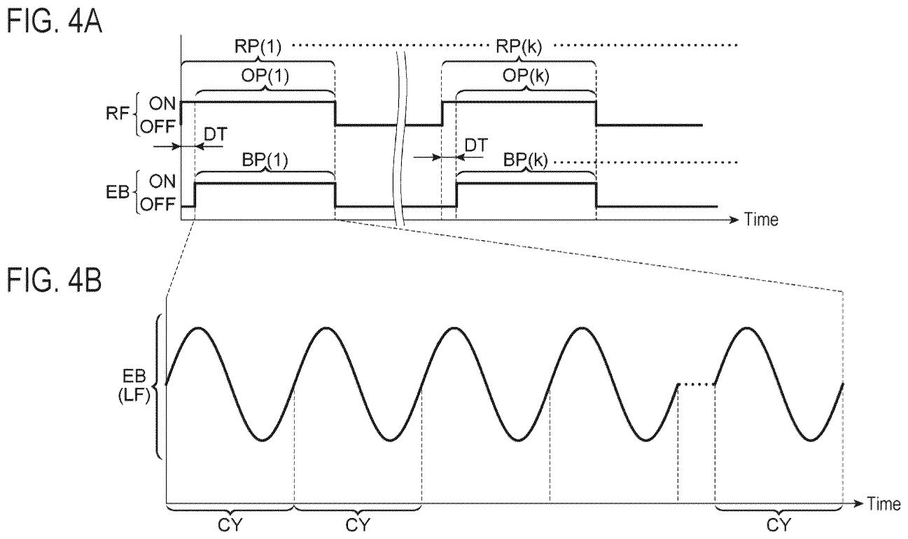

The electric bias EB may be bias radio-frequency power with the bias frequency (see “LF” in FIG. 4B). That is, the electric bias EB may have a sinusoidal waveform with the bias frequency. In this case, the bias power supply 32 is electrically connected to the bias electrode via a matcher 32m. A variable impedance of the matcher 32m is set to reduce reflections from a load of the bias radio-frequency power.

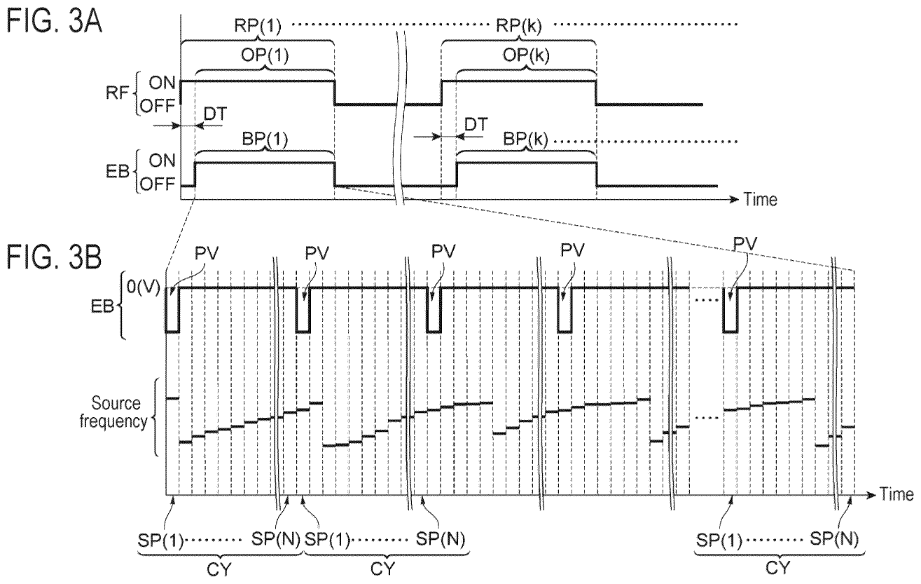

Alternatively, the electric bias EB may include a voltage pulse (see “PV” in FIG. 3B). The voltage pulse is applied to the bias electrode within the waveform cycle CY. The voltage pulse is periodically applied to the bias electrode at time intervals equal to the time length of the waveform cycle CY. The waveform of the voltage pulse may be a rectangular, triangular, or arbitrary shape. A voltage polarity of the voltage pulse may be set to create a potential difference between the substrate W and the plasma so that ions from the plasma are drawn into the substrate W. The voltage pulse may be a negative voltage pulse or a negative direct current voltage pulse. When the electric bias EB includes the voltage pulse, the plasma processing apparatus 1 may not include the matcher 32m.

The plasma processing apparatus 1 may further include a directional coupler 31d. The directional coupler 31d is connected between the radio-frequency power supply 31 and the radio-frequency electrode (or the matcher 31m). The directional coupler 31d is configured to measure a power level of travelling waves of the source radio-frequency power RF and a power level of reflected waves of the source radio-frequency power RF.

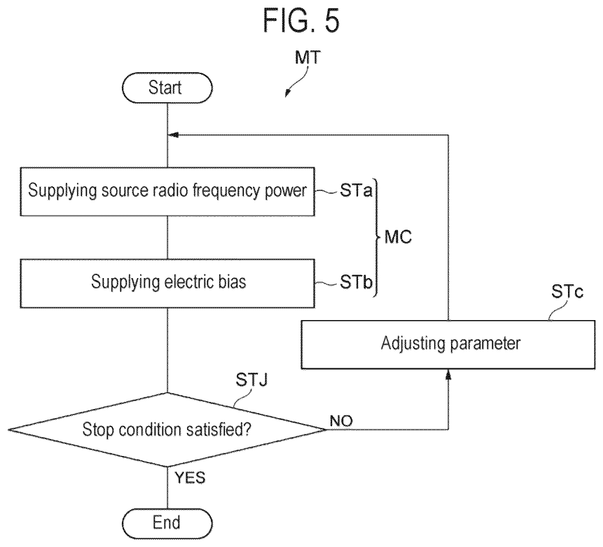

Hereinafter, the control of individual parts of the plasma processing apparatus 1 and a plasma processing method according to one exemplary embodiment will be described with reference to FIG. 2, FIGS. 3A and 3B, FIGS. 4A and 4B, and FIG. 5. FIGS. 3A and 3B and FIGS. 4A and 4B are timing charts, respectively, relating to the plasma processing apparatus according to one exemplary embodiment. In FIGS. 3A and 4A, “ON” for the source radio-frequency power RF indicates that the source radio-frequency power RF is being supplied, while “OFF” for the source radio-frequency power RF indicates that the supply of the source radio-frequency power RF is stopped. Further, “ON” for the electric bias EB indicates that the electric bias EB is being supplied, and “OFF” for the electric bias EB indicates that the supply of the electric bias EB is stopped. FIG. 5 is a flowchart of the plasma processing method according to one exemplary embodiment.

The controller 2 is configured to perform the plasma processing method (hereinafter referred to as “method MT”) by controlling individual parts of the plasma processing apparatus 1. In addition, the method MT may be performed by controlling the radio-frequency power supply 31 and the bias power supply 32 by a pulse controller 34 to be described later, or by controlling individual parts of the plasma processing apparatus 1 in cooperation between the controller 2 and the pulse controller 34. During a period in which the method MT is being performed, the substrate W may or may not be placed on the substrate support 11. The controller 2 is configured to execute Operation STa and Operation STb of the method MT, as illustrated in FIG. 5.

In Operation STa, the controller 2 controls the radio-frequency power supply 31 to supply the source radio-frequency power RF in order to generate plasma from a gas inside the chamber 10. The gas from which the plasma is generated is supplied into the chamber 10 from the gas supplier 20. An internal pressure of the chamber 10 is adjusted to a specified pressure by the exhaust system 40.

In Operation STb, the controller 2 controls the bias power supply 32 to supply the electric bias to the substrate support 11 (or bias electrode thereof) while the source radio-frequency power RF is being supplied.

As illustrated in FIGS. 3A and 4A, the controller 2 delays the supply of the electric bias EB by a delay time length DT from a time point at which the supply of the source radio-frequency power RF begins. The delay time length DT is set to be equal to or greater than a reference time length. The reference time length is a time length for electrons to reach an end portion of the substrate support 11 or an end portion of the substrate W on the substrate support 11 from the center of the substrate support 11 or the center of the substrate W. The delay time length DT may be 300 nanoseconds or more, 400 nanoseconds or more, 500 nanoseconds or more, or 600 nanoseconds or more. The delay time length DT may also be 3 microseconds or less, 2 microseconds or less, or 1 microsecond or less.

The power level and source frequency f_{RF} of the source radio-frequency power RF during the delay time length DT and during the period from the time point at which the supply of the source radio-frequency power RF begins to the time point at which the supply of the electric bias EB begins (hereinafter referred to as “preceding supply period”) are determined in advance. The power level and source frequency f_{RF} of the source radio-frequency power RF during the delay time length DT and during the preceding supply period are assigned to the radio-frequency power supply 31 by the controller 2. The power level and source frequency f_{RF} of the source radio-frequency power RF during the delay time length DT and the preceding supply period are optimized in advance to ensure uniformity of a plasma density distribution or plasma processing on the substrate. The plasma density distribution may be an emission intensity distribution inside the chamber 10 as acquired through an optical window by an emission analyzer 50. The uniformity of the plasma processing on the substrate may be evaluated based on an in-plane distribution of an etching rate on the substrate, or a distribution of an inclination angle of holes formed in the substrate by etching.

As illustrated in FIG. 5, the controller 2 may repeat a cycle MC including Operation STa and Operation STb. In this case, in Operation STJ, it is determined whether or not a stop condition is satisfied. The stop condition is satisfied when the number of repetitions of the cycle MC reaches a predetermined count. When the stop condition is not satisfied, the cycle MC is performed again. When the stop condition is satisfied, the method MT terminates.

By repeating the cycle MC, the supply of the pulses of both the source radio-frequency power RF and the electric bias EB are repeated. In other words, as illustrated in FIGS. 3A and 4A, by the repetition of the cycle MC, the supply of the source radio-frequency power RF (in the drawing, “ON” for RF) and the cutoff of the source radio-frequency power RF (in the drawing, “OFF” for RF) are performed in an alternate manner. Further, the supply of the electric bias EB (in the drawing, “ON” for EB) and the cutoff of the electric bias EB (in the drawing, “OFF” for EB) are performed in an alternate manner. As illustrated in FIGS. 3B and 4B, the period during which the electric bias EB is ON (i.e., a pulse ON period BP of the electric bias EB) includes the repetition of the waveform cycle CY. In other words, during the pulse ON period BP of the electric bias EB, the electric bias EB is supplied periodically at the waveform cycle CY. The period during which the source radio-frequency power RF is ON (i.e., a pulse ON period RP of the source radio-frequency power RF) and the pulse ON period of the electric bias EB may be assigned to the radio-frequency power supply 31 and the bias power supply 32 by pulse signals from the pulse controller 34.

The controller 2 may further execute Operation STc. In Operation STc, the controller 2 adjusts parameters to enhance the uniformity of the plasma density distribution in Operation STa of a subsequent cycle MC according to the plasma density distribution obtained in Operation STa of the preceding cycle MC. The parameters include the power level and source frequency f_{RF} of the source radio-frequency power RF during the delay time length DT and the preceding supply period. In addition, as described above, the plasma density distribution may be the emission intensity distribution inside the chamber 10 as acquired by the emission analyzer 50.

In one embodiment, the controller 2 may adjust a set power level of the source radio-frequency power RF to bring an effective power level of the source radio-frequency power RF during the preceding supply period closer to a target value. The effective power level is specified as a difference between the power level of the travelling waves and the power level of the reflected waves during the preceding supply period in the preceding cycle MC. The power level of the travelling waves and the power level of the reflected waves are acquired by the directional coupler 31d. To bring the specified effective power level closer to the target value, the controller 2 adjusts the set power level of the source radio-frequency power RF during the preceding supply period in the subsequent cycle MC.

In one embodiment, as illustrated in FIG. 3B, the radio-frequency power supply 31 may change the source frequency f_{RF} of the source radio-frequency power RF within the waveform cycle CY of the electric bias EB during an overlap period OP, so as to reduce a degree of reflection of the source radio-frequency power RF from a load. Specifically, the radio-frequency power supply 31 may adjust the source frequency f_{RF} to reduce the degree of reflection of the source radio-frequency power RF for each of plurality of phase periods SP (see FIG. 3B) in the waveform cycle CY during the overlap period OP. The overlap period OP is a period during which the source radio-frequency power RF and the electric bias EB are supplied in a simultaneous manner. The source frequency f_{RF} for each of the plurality of phase periods SP in the waveform cycle CY may be set using a previously-prepared initial table. Further, the adjustment of the source frequency may be performed by a first feedback and/or a second feedback to be described later.

According to the plasma processing apparatus 1 as described above, even if the electric field is locally strong around the substrate support 11 or the substrate W at an initial stage of plasma ignition, the electric bias EB is supplied after electrons have spread across the entire substrate support 11 or the substrate W to achieve uniform plasma generation. Accordingly, the plasma processing apparatus 1 improves the uniformity of the plasma density distribution.

Here, a diffusion time of electrons from a position on the center of the substrate W placed on the substrate support 11 to a position on the edge of the substrate W is considered. When electrons in the plasma follow the Maxwell distribution, average velocities <vₓ>, <v_{y}> and <v_{z}> of electrons in x, y, and z directions, which are perpendicular to each other, are represented by the equation below. Here, m is the electron mass, k_{B} is the Boltzmann constant, and T is the electron temperature. The x direction and the y direction are parallel to the substrate W, while the z direction is perpendicular to the substrate W.

$$\frac{1}{2} m 〈 {v}_{x}^{2} 〉 = \frac{1}{2} {k}_{B} T , \frac{1}{2} m 〈 {v}_{y}^{2} 〉 = \frac{1}{2} {k}_{B} T , \frac{1}{2} m 〈 {v}_{z}^{2} 〉 = \frac{1}{2} {k}_{B} T \qquad [ Equation 1 ]$$

When the electron temperature is 10,000 K, <vₓ> and <v_{y}> are 3.89×10⁵ m/s. Further, a magnitude of a velocity in the x-y plane is the square root of the sum of the squares of <vₓ> and <v_{y}>. Thus, the magnitude becomes 5.51×10⁵ m/s. Therefore, when the distance from the position on the center of the substrate W to the position on the edge of the substrate W is 150 mm, a time required for the electrons in the plasma to diffuse from the position on the center of the substrate W to the position on the edge of the substrate W becomes 272 nanoseconds. Accordingly, when the delay time length DT is 300 ns or more, the electrons sufficiently diffuse across the substrate W and the plasma is uniformly generated. Thereafter, the electric bias EB may be supplied.

Hereinafter, the first feedback and the second feedback will be described.

### [First Feedback]

The first feedback is performed to adjust the source frequency for the plurality of phase periods SP in each of the plurality of waveform periods CY within the overlap period OP. Each of the plurality of waveform periods CY includes N phase periods SP(1) to SP(N), where N is an integer equal to or greater than 2. The N phase periods SP(1) to SP(N) divide each of the plurality of waveform periods CY into N phase periods. In the following description, a waveform period CY(m) represents an m^{th} waveform period among a plurality of consecutive waveform periods CY. A phase period SP(n) represents an n^{th} phase period among the phase periods SP(1) to SP(N). Further, a phase period SP(m, n) represents the n^{th} phase period in the waveform period CY(m).

The adjustment of the source frequency in the first feedback may be performed by the radio-frequency power supply 31. The radio-frequency power supply 31 adjusts the source frequency of the source radio-frequency power RF in the phase period SP(m, n) in response to a change in the degree of reflection of the source radio-frequency power RF.

In order to determine the degree of reflection of the source radio-frequency power RF, the plasma processing apparatus 1 may use the directional coupler 31d. The power level Pr of reflected waves measured by the directional coupler 31d is notified to the radio-frequency power supply 31. Further, the power level Pf of the travelling waves may be notified from the directional coupler 31d to the radio-frequency power supply 31.

The plasma processing apparatus 1 may further include a sensor 31s. The sensor 31s includes a voltage sensor and a current sensor. The sensor 31s is configured to measure a voltage V_{RF} and a current I_{RF} in a power supply path that connects the radio-frequency power supply 31 and the radio-frequency electrode to each other. The source radio-frequency power RF is supplied to the radio-frequency electrode via the power supply path. The sensor 31s may be provided between the radio-frequency power supply 31 and the matcher 31m. The voltage V_{RF} and the current I_{RF} are notified to the radio-frequency power supply 31.

The radio-frequency power supply 31 generates a representative value from the measured values in each of the plurality of phase periods SP. The measured value may be the power level Prof the reflected wave acquired by the directional coupler 31d. The measured value may be a value of a ratio of the power level Pr of the reflected wave to an output power level of the source radio-frequency power RF (i.e., the reflectance). The measured value may be a phase difference θ between the voltage V_{RF} and the current I_{RF} acquired by the sensor 31s in each of the plurality of phase periods SP. The measured value may be an impedance Z on the load side of the radio-frequency power supply 31 in each of the plurality of phase periods SP. The impedance Z is determined from the voltage V_{RF} and the current I_{RF} acquired by the sensor 31s. The representative value may be an average value or a maximum value of the measured values in each of the plurality of phase periods SP. The radio-frequency power supply 31 uses the representative value in each of the plurality of phase periods SP as a value representing the degree of reflection of the source radio-frequency power RF.

In the first feedback, the radio-frequency power supply 31 specifies a change in the degree of reflection by using different source frequencies in the corresponding phase periods SP(n) in each of two or more waveform periods CY prior to the waveform period CY(m).

By using the different source frequencies in the phase periods SP(n) in each of two or more waveform periods CY, it is possible to specify a relationship between the change in source frequency (frequency shift) and the change in the degree of reflection of the source radio-frequency power. Therefore, according to the plasma processing apparatus 1, it is possible to adjust the source frequency used in the phase period SP(m, n) in response to the change in the degree of reflection so as to reduce the degree of reflection. Further, according to the plasma processing apparatus 1, it is possible to quickly reduce the degree of reflection in each of the waveform periods CY in which the electric bias EB is applied to the bias electrode of the substrate support 11.

In one embodiment, the two or more waveform periods CY prior to the waveform period CY(m) include a waveform period CY(m−M₁) and a waveform period CY(m−M₂), where M₁ and M₂ are natural numbers that satisfy M₁>M₂. In one embodiment, the waveform period CY(m−M₁) is a waveform period CY(m−2Q), and the waveform period CY(m−M₂) is a waveform period CY(m−Q). “Q” and “M₂” may be “1”, and “2Q” and “M₁” may be “2”. “Q” may be an integer equal to or greater than 2.

In the first feedback, the radio-frequency power supply 31 gives, to a source frequency f(m−M₂, n), a one-direction frequency shift from the source frequency f(m−M₁, n), where f(m, n) represents the source frequency of the source radio-frequency power RF used in the phase period SP(m, n). f(m, n) is expressed as f(m, n)=f(m−M₂, n)+Δ(m, n). Δ(m, n) represents an amount of the frequency shift. The one-direction frequency shift is one of a frequency decrease and a frequency increase. When the one-direction frequency shift is a frequency decrease, Δ(m, n) has a negative value. When the one-direction frequency shift is a frequency increase, Δ(m, n) has a positive value.

In the first feedback, when the degree of reflection is reduced by using the source frequency f(m−M₂, n) obtained by the one-direction frequency shift, the radio-frequency power supply 31 sets the source frequency f(m, n) to a frequency having the one-direction frequency shift with respect to the source frequency f(m−M₂, n). For example, when the power level Pr(m−M₂, n) is reduced from the power level Pr(m−M₁, n) by the one-direction frequency shift, the radio-frequency power supply 31 sets the source frequency f(m, n) to a frequency having the one-direction frequency shift with respect to the source frequency f(m−M₂, n). Pr(m, n) represents the power level Pr of the reflected wave of the source radio-frequency power RF in the phase period SP(m, n).

In the first feedback, the degree of reflection may be increased by using the source frequency f(m−M₂, n) obtained by the one-direction frequency shift. For example, the power level Pr(m−M₂, n) of the reflected wave may be increased from the power level Pr(m−M₁, n) of the reflected wave by the one-direction frequency shift. In this case, the radio-frequency power supply 31 may set the source frequency f(m, n) to a frequency having a frequency shift in the other direction with respect to the source frequency f(m−M₂, n).

In another embodiment, the source frequency of the source radio-frequency power RF in the phase period SP(m, n) may be determined as a frequency that minimizes the degree of reflection from two or more degrees of reflection (e.g., power levels Pr) obtained by using different source frequencies in the corresponding phase periods SP(n) in two or more waveform periods CY prior to the waveform period CY(m). The frequency that minimizes the degree of reflection may be determined by a least square method using each of the different frequencies and the corresponding degrees of reflection.

### [Second Feedback]

Next, the second feedback will be described. In the following description, the waveform cycle CY(m) indicates an m^{th} waveform cycle among a plurality of waveform cycles CY(1) to CY(M) during each of a plurality of overlap periods OP. Further, the waveform cycle CY(k, m) indicates the m^{th} waveform cycle during the k^{th} overlap period. Further, the phase period SP(n) indicates an n^{th} phase period among a plurality of phase periods SP(1) to SP(N) in each of the plurality of waveform cycles CY during each of the plurality of overlap periods OP. Further, the phase period SP(m, n) indicates an n^{th} phase period in the waveform cycle CY(m). Further, the phase period SP(k, m, n) indicates the n^{th} phase period in the waveform cycle CY(m) during the k^{th} overlap period OP(k).

The source frequency in each of the plurality of phase periods SP in each of the plurality of waveform cycles CY during each of the overlap periods OP(1) to OP(T−1) may be adjusted by the above-described first feedback. Here, T is an integer greater than or equal to 3. Alternatively, the source frequency in each of the plurality of phase periods SP in each of the plurality of waveform cycles CY in each of the overlap periods OP(1) to OP(T−1) may be set to a frequency registered in the previously-prepared initial table.

The source frequency for the source radio-frequency power RF during the overlap period subsequent to the overlap period OP(T) may be adjusted using the second feedback. In the second feedback, the radio-frequency power supply 31 adjusts the source frequency f(k, m, n) according to the aforementioned change in the degree of reflection of the source radio-frequency power RF. In the second feedback, the change in the degree of reflection is specified by using different source frequencies of the source radio-frequency power RF in the corresponding phase period SP(n) in the waveform cycle CY(m) during two or more overlap periods OP preceding the overlap period OP(k).

In the second feedback, by using the different source frequencies in the same phase period in the same waveform period in each of the two or more overlap periods OP, it is possible to specify a relationship between the change in source frequency (frequency shift) and the change in the degree of reflection of the source radio-frequency power. Therefore, according to the second feedback, it is possible to adjust the source frequency used in the phase period SP(k, m, n) in response to the change in the degree of reflection so as to reduce the degree of reflection. Further, according to the second feedback, it is possible to quickly reduce the degree of reflection in each of the plurality of waveform periods CY in each of the plurality of overlap periods OP.

In one embodiment, the two or more overlap periods OP preceding the overlap period OP(k) include a (k−K1)^{th} overlap period OP(k−K₁) and a (k−K₂)^{th} overlap period OP(k−K₂). Here, K₁ and K₂ are natural numbers that satisfy K₁>K₂.

In one embodiment, the overlap period OP(k−K₁) is represented as an overlap period OP(k−2). The overlap period OP(k−K₂) is an overlap period subsequent to the overlap period OP(k−K₁), which is also represented as an overlap period OP(k−1) in one embodiment. That is, in one embodiment, K₂ and K₁ are 1 and 2, respectively.

The radio-frequency power supply 31 gives, to the source frequency f(k−K₂, m, n) in the phase period SP(k−K₂, m, n), a one-direction frequency shift from the source frequency in the phase period SP(k−K₁, m, n). Here, f(k, m, n) represents the source frequency of the source radio-frequency power RF used in the phase period SP(k, m, n). f(k, m, n) is expressed as f(k, m, n)=f(k−K₂, m, n)+Δ(k, m, n). Δ(k, m, n) represents an amount of the frequency shift. The one-direction frequency shift is one of a frequency decrease and a frequency increase. When the one-direction frequency shift is a frequency decrease, Δ(k, m, n) has a negative value. When the one-direction frequency shift is a frequency increase, Δ(k, m, n) has a positive value.

In the second feedback, when the degree of reflection is reduced by using the source frequency f(k−K₂, m, n) obtained by the one-direction frequency shift, the radio-frequency power supply 31 sets the source frequency f(k, m, n) to a frequency having the one-direction frequency shift with respect to the source frequency f(k−K₂, m, n). For example, when the power level Pr(k−K₂, m, n) is reduced from the power level Pr(k−K₁, m, n) by the one-direction frequency shift, the radio-frequency power supply 31 sets the source frequency f(k, m, n) to a frequency having the one-direction frequency shift with respect to the source frequency f(k−K₂, m, n). Pr(k, m, n) represents the power level Pr of the reflected wave of the source radio-frequency power RF in the phase period SP(k, m, n).

In the second feedback, the degree of reflection may be increased by using the source frequency f(k−K₂, m, n) obtained by a one-direction frequency shift. For example, the power level Pr(k−K₂, m, n) of the reflected wave may be increased from the power level Pr(k−K₁, m, n) of the reflected wave by the one-direction frequency shift. In this case, the radio-frequency power supply 31 may set the source frequency f(k, m, n) to a frequency having a frequency shift in the other direction with respect to the source frequency f(k−K₂, m, n).

In another embodiment, the plurality of overlap periods OP may include a first to Kₐ^{th} overlap periods OP(1) to OP(Kₐ). Here, Kₐ is a natural number greater than or equal to 2. The radio-frequency power supply 31 may perform an initial processing in a first to Mₐ^{th} waveform cycles CY(1) to CY(Mₐ) among the plurality of waveform cycles CY included in each of the overlap periods OP(1) to OP(Kₐ). Here, Mₐ is a natural number. In the initial processing, a frequency set group including a plurality of frequency sets for the respective waveform cycles CY(1) to CY(Mₐ) may be used. The plurality of frequency sets included in the frequency set group may differ from each other. Further, a plurality of frequency set groups for each of the overlap periods OP(1) to OP(Kₐ) may be used. The plurality of frequency set groups may differ from each other. The radio-frequency power supply 31 uses a plurality of frequencies included in the corresponding frequency set, as source frequencies for the plurality of phase periods SP in each of the first to Mₐ^{th} waveform cycles CY(1) to CY(Mₐ) during each of the overlap periods OP(1) to OP(Kₐ). In addition, the plurality of frequency sets and the plurality of frequency set groups may be stored in a memory of either the controller 2 or the radio-frequency power supply 31.

The radio-frequency power supply 31 may perform the above-described first feedback after the waveform cycle CY(Mₐ) among the plurality of waveform cycles CY during each of the overlap periods OP(1) to OP(Kₐ). In other words, the radio-frequency power supply 31 may perform the above-described first feedback in the waveform cycles CY(Mₐ+1) to CY(M) included in each of the overlap periods OP(1) to OP(Kₐ).

In one embodiment, the plurality of overlap periods OP may further include a (Kₐ+1)^{th} to K_{b}^{th} overlap periods OP(Kₐ+1) to OP(K_{b}). Here, K_{b} is a natural number equal to or greater than (Kₐ+1), and may satisfy a relationship of K_{b}=Kₐ+1.

The radio-frequency power supply 31 may perform the initial processing in each of the first to M_{b1}^{th} waveform cycles CY(1) to CY(M_{b1}) among the plurality of waveform cycles included in each of the overlap periods OP(Kₐ+1) to OP(K_{b}). Here, M_{b1} is a natural number. M_{b1} and Mₐ may satisfy a relationship of M_{b1}<M₈.

The radio-frequency power supply 31 may perform the above-described second feedback in a (M_{b1}+1)^{th} to M_{b2}^{th} waveform cycles CY(M_{b1}+1) to CY(M_{b2}) among the plurality of waveform cycles CY included in each of the overlap periods OP(Kₐ+1) to OP(K_{b}). Here, M_{b2} is a natural number that satisfies a relationship of M_{b2}>M_{b1}.

The radio-frequency power supply 31 may perform the above-described first feedback after the waveform cycle CY(M_{b2}) during each of the overlap periods OP(Kₐ+1) to OP(K_{b}). In other words, the radio-frequency power supply 31 may perform the above-described first feedback in the waveform cycles CY(M_{b2}+1) to CY(M) included in each of the overlap periods OP(Kₐ+1) to OP(K_{b}).

Further, the radio-frequency power supply 31 may perform the above-described second feedback in the first to the M_{c}^{th} waveform cycles CY(1) to CY(M_{c}) included in each of (K_{b}+1)^{th} to the last overlap periods OP(K_{b}+1) to OP(K). Here, M_{c} is a natural number. Further, the radio-frequency power supply 31 may perform the above-described first feedback after the waveform cycle CY(M_{c}) during each of the overlap periods OP(K_{b}+1) to OP(K). In other words, the radio-frequency power supply 31 may perform the above-described first feedback in the waveform cycles CY(M_{c}+1) to CY(M) included in each of the overlap periods OP(K_{b}+1) to OP(K).

In another embodiment, in the first feedback, the source frequency of the source radio-frequency power RF for the phase period SP(k, m, n) may be determined as a frequency that minimizes the degree of reflection from two or more degrees of reflection (e.g., power level Pr) obtained by using different source frequencies of the source radio-frequency power RF for the corresponding phase period SP(n) in each of the two or more waveform cycles CY preceding the waveform cycle CY(k, m) during the overlap period OP(k). The frequency that minimizes the degree of reflection may be obtained by a least square method using each of the different frequencies and the corresponding degrees of reflection.

Further, in the second feedback, the source frequency f(k, m, n) may be determined as a frequency that minimizes the degree of reflection from two or more degrees of reflection (e.g., power level Pr) obtained by using different source frequencies of the source radio-frequency power RF for the corresponding phase period SP(n) in the waveform cycle CY(m) during two or more overlap periods OP preceding the overlap period OP(k). The frequency that minimizes the degree of reflection may be obtained by the least square method using each of the different frequencies and the corresponding degrees of reflection.

Although various exemplary embodiments have been described above, the present disclosure is not limited to the above-described exemplary embodiments, and various additions, omissions, substitutions, and modifications may be made. In addition, elements in different embodiments may be combined to form other embodiments.

Various exemplary embodiments included in the present disclosure are now described in [E1] to [E10] below.

### [E1]

A plasma processing apparatus includes: a chamber; a substrate support provided inside the chamber; a radio-frequency power supply configured to generate source radio-frequency power; a bias power supply electrically coupled to the substrate support and configured to generate electric bias for drawing ions to the substrate support; and a controller configured to control the radio-frequency power supply and the bias power supply. The controller is configured to execute a first operation of supplying the source radio-frequency power to generate plasma inside the chamber, and a second operation of supplying the electric bias to the substrate support during the supply of the source radio-frequency power. A delay time length from a time point at which the supply of the source radio-frequency power begins in the first operation until a time point at which the supply of the electric bias begins in the second operation is set to be equal to or greater than a reference time length, and the reference time length is a time length for an electron to reach an end portion of the substrate support or an end portion of a substrate on the substrate support from a center of the substrate support or a center of the substrate on the substrate support.

In the embodiment of [E1] above, even if the electric field is locally strong around the substrate support or the substrate at the initial stage of plasma ignition, the electric bias is supplied after electrons have spread across the entire substrate support or the entire substrate to achieve uniform plasma generation. Accordingly, the uniformity of the plasma density distribution is improved.

### [E2]

In the plasma processing apparatus of [E1] above, the delay time length is 300 nanoseconds or more.

### [E3]

In the plasma processing apparatus of [E1] or [E2] above, the electric bias is a bias radio-frequency power or a periodic voltage pulse.

### [E4]

In the plasma processing apparatus of any one of [E1] to [E3] above, the radio-frequency power source is configured to change a source frequency of the source radio-frequency power within a waveform cycle of the electric bias so as to reduce a degree of reflection of the source radio-frequency power from a load.

### [E5]

In the plasma processing apparatus of any one of [E1] to [E4] above, the controller is configured to: execute a repetition of a cycle including the first operation and the second operation to repeatedly supply a pulse of the source radio-frequency power and a pulse of the electric bias, and adjust the delay time length, a power level of the source radio-frequency power, and a source frequency of the source radio-frequency power to enhance uniformity of a second plasma density distribution obtained in a second round of the first operation based on a first plasma density distribution obtained in a first round of the first operation in the repetition of the cycle.

### [E6]

A plasma processing method includes: a first operation of supplying, by a radio-frequency power supply, source radio-frequency power to generate plasma inside a chamber of a plasma processing apparatus; and a second operation of supplying, by a bias power supply, electric bias to a substrate support provided inside the chamber to draw ions into the substrate support. A delay time length from a time point at which the supply of the source radio-frequency power begins in the first operation until a time point at which the supply of the electric bias begins in the second operation is set to be equal to or greater than a reference time length, and the reference time length is a time length for an electron to reach an end portion of the substrate support or an end portion of a substrate on the substrate support from a center of the substrate support or a center of the substrate on the substrate support.

### [E7]

In the plasma processing method of [E6] above, the delay time length is 300 nanoseconds or more.

### [E8]

In the plasma processing method of [E6] or [E7] above, the electric bias is a bias radio-frequency power or a periodic voltage pulse.

### [E9]

The plasma processing method of any one of [E6] to [E8] above further includes changing a source frequency of the source radio-frequency power within a waveform cycle of the electric bias to reduce a degree of reflection of the source radio-frequency power from a load.

### [E10]

The plasma processing method of any one of [E6] to [E9] above further includes: repeating a cycle including the first operation and the second operation to repeatedly supply a pulse of the source radio-frequency power and a pulse of the electric bias, and adjusting the delay time length, a power level of the source radio-frequency power, and a source frequency of the source radio-frequency power to enhance uniformity of a second plasma density distribution obtained in a second round of the first operation based on a first plasma density distribution obtained in a first round of the first operation in the repetition of the cycle.

According to the present disclosure, it is possible to improve the uniformity of plasma density distribution.

From the foregoing description, it should be understood that various embodiments of the present disclosure have been described herein for purposes of illustration, and that various modifications may be made without departing from the scope and spirit of the present disclosure. Accordingly, the various embodiments disclosed herein are not intended to be limiting, and the true scope and spirit of the present disclosure are indicated by the appended claims.

What is claimed is:

1. A plasma processing apparatus, comprising:
a chamber;
a substrate support provided inside the chamber;
a radio-frequency power supply configured to generate source radio-frequency power;
a bias power supply electrically coupled to the substrate support and configured to generate electric bias for drawing ions to the substrate support; and
a controller configured to control the radio-frequency power supply and the bias power supply,
wherein the controller is configured to execute:
a first operation of supplying the source radio-frequency power to generate plasma inside the chamber; and
a second operation of supplying the electric bias to the substrate support during the supply of the source radio-frequency power,
wherein a delay time length from a time point at which the supply of the source radio-frequency power begins in the first operation until a time point at which the supply of the electric bias begins in the second operation is set to be equal to or greater than a reference time length, and
wherein the reference time length is a time length for an electron to reach an end portion of the substrate support or an end portion of a substrate on the substrate support from a center of the substrate support or a center of the substrate on the substrate support.

2. The plasma processing apparatus of claim 1, wherein the delay time length is 300 nanoseconds or more.

3. The plasma processing apparatus of claim 1, wherein the electric bias is a bias radio-frequency power or a periodic voltage pulse.

4. The plasma processing apparatus of claim 1, wherein the radio-frequency power source is configured to change a source frequency of the source radio-frequency power within a waveform cycle of the electric bias so as to reduce a degree of reflection of the source radio-frequency power from a load.

5. The plasma processing apparatus of claim 1, wherein the controller is configured to:
execute a repetition of a cycle including the first operation and the second operation to repeatedly supply a pulse of the source radio-frequency power and a pulse of the electric bias, and
adjust the delay time length, a power level of the source radio-frequency power, and a source frequency of the source radio-frequency power to enhance uniformity of a second plasma density distribution obtained in a second round of the first operation based on a first plasma density distribution obtained in a first round of the first operation in the repetition of the cycle.

6. A plasma processing method, comprising:
a first operation of supplying, by a radio-frequency power supply, source radio-frequency power to generate plasma inside a chamber of a plasma processing apparatus; and
a second operation of supplying, by a bias power supply, electric bias to a substrate support provided inside the chamber to draw ions into the substrate support,
wherein a delay time length from a time point at which the supply of the source radio-frequency power begins in the first operation until a time point at which the supply of the electric bias begins in the second operation is set to be equal to or greater than a reference time length, and
wherein the reference time length is a time length for an electron to reach an end portion of the substrate support or an end portion of a substrate on the substrate support from a center of the substrate support or a center of the substrate on the substrate support.

7. The plasma processing method of claim 6, wherein the delay time length is 300 nanoseconds or more.

8. The plasma processing method of claim 6, wherein the electric bias is a bias radio-frequency power or a periodic voltage pulse.

9. The plasma processing method of claim 6, further comprising: changing a source frequency of the source radio-frequency power within a waveform cycle of the electric bias to reduce a degree of reflection of the source radio-frequency power from a load.

10. The plasma processing method of claim 6, further comprising:
repeating a cycle including the first operation and the second operation to repeatedly supply a pulse of the source radio-frequency power and a pulse of the electric bias, and
adjusting the delay time length, a power level of the source radio-frequency power, and a source frequency of the source radio-frequency power to enhance uniformity of a second plasma density distribution obtained in a second round of the first operation based on a first plasma density distribution obtained in a first round of the first operation in the repetition of the cycle.
